(19) United States
(12) Patent Application Publication
(10) Pub. No.: US 2025/0199087 A1
(43) Pub. Date: Jun. 19, 2025

(54) LEAKAGE CURRENT METAL DETECTION CIRCUIT DEVICE

(71) Applicant: DongGuan City TuoCheng Industries Co., Ltd, Dongguan City (CN)

(72) Inventor: Quan-Yu CAI, Dongguan City (CN)

(21) Appl. No.: 18/423,537

(22) Filed: Jan. 26, 2024

(30) Foreign Application Priority Data
Dec. 15, 2023 (CN) 202323448813.0

(51) Int. Cl. G01R 31/58

(52) U.S. Cl. CPC G01R 31/58

(57) ABSTRACT

The present invention relates to a leakage current metal detection circuit device including a detection wire and a detection device. The detection wire has a metal detection wire, an additional signal wire, a metal outer layer, a protective insulation layer, and multiple core wires. The additional signal wire, the metal detection wire, and the core wires are all wrapped by the metal outer layer and further enveloped by the protective insulation layer.

### FIELD OF INVENTION

The present invention relates to the technical field of leakage current detection, in particular to a leakage current metal detection circuit device.

### BACKGROUND OF THE INVENTION

Cables are crucial connecting components for signal transmission or power supply. In the course of long-term use, damage, rupture, or breakage are inevitable. However, due to an external protective insulation layer of cables, it is not easy to identify the damage to the internal structure of the cable, resulting in delayed repairs and potentially causing damage to electrical facilities. Existing technology generally strengthens the durability of the cable core wire to extend the overall service life, such as the use of braided wires. Nonetheless, there is still a risk of wire breakage and current leakage, for instance, damage from rodents or other small animals. If not detected early, electrical hazards persist.

### SUMMARY OF THE INVENTION

The present invention aims to address the problems of the existing technology by providing a leakage current metal detection circuit device, which incorporates a metal detection wire and an additional signal wire connected to a sensing end S1 and a sensing end S2. When the metal detection wire is broken, the connection between the sensing end S1 and sensing end S2 is interrupted, enabling the detection device to promptly detect and thus timely identify the risk of leakage current.

To solve the above technical problem, the present invention adopts the following technical solution: the leakage current metal detection circuit device, comprising the detection wire and the detection device. The detection wire comprises a metal detection wire, an additional signal wire, a metal outer layer, a protective insulation layer, and multiple core wires. The additional signal wire, the metal detection wire, and the core wires are all wrapped by the metal outer layer, which is then enveloped by the protective insulation layer.

The detection device is equipped with the sensing end S1 and the sensing end S2. One end of the metal detection wire is connected to one end of the additional signal wire and the other end is connected to the sensing end S1, while the other end of the additional signal wire is connected to the sensing end S2. This arrangement allows the detection device to detect if the electrical connection between sensing end S1 and sensing end S2 is interrupted.

Preferably, the core wire comprises a first conductor group and a first insulation layer enveloping the first conductor group.

Preferably, the metal detection wire is a bare copper wire.

Preferably, the additional signal wire comprises a second conductor group and a third insulation layer enveloping the second conductor group.

Preferably, the metal outer layer is an aluminum foil layer.

Preferably, the core wire further comprises a second insulation layer enveloping the first insulation layer.

Preferably, the detection device comprises an input terminal L, an input terminal N, an output terminal LO, an output terminal NO, a main switch S1, a drive module, a switch module, and a circuit breaker X1. The drive module is equipped with the sensing end S1 and sensing end S2.

The input terminal L is connected to the output terminal LO through the main switch S1, and the input terminal N is also connected to the output terminal NO through the main switch S1.

The input of the drive module is connected to the output terminal LO, and the output of the drive module is connected to the control end of the switch module. The drive module operates according to the connection signals between the sensing end S1 and sensing end S2 to control the on/off of the switch module. The input of the switch module is connected to the output terminal LO and the output is connected to one voltage end of the circuit breaker X1, while the other voltage end of the circuit breaker X1 is connected to the output terminal NO. The control end of the circuit breaker X1 is connected to the control end of the main switch S1 and is used to control the on/off of the main switch S1.

Preferably, the input terminal N is connected to a rectifier D1 through the main switch S1. The switch module comprises a diode Q1 and a diode Q2, wherein an anode of the diode Q1 is connected to the output of the rectifier D1, and a cathode of the diode Q1 is grounded. The control end of the diode Q1 is connected to the output of the drive module. Similarly, an anode of the diode Q2 is connected to the output of the rectifier D1, and a cathode of the diode Q2 is grounded. The control end of the diode Q2 is connected to the output of the drive module.

Preferably, the drive module comprises resistors R5, R18, R4, and R17. The output of the rectifier D1 is connected sequentially through the resistor R18 and the resistor R5, and then connected to the control end of diode Q1. The connection end between the resistor R18 and the resistor R5 is connected to the sensing end S1. The control end of diode Q2 is connected sequentially through the resistor R4 and the resistor R17, and then connected to the ground. The connection end between the resistor R4 and the resistor R17 is connected to the sensing end S2.

### BENEFICIAL EFFECTS OF THE PRESENT INVENTION

The leakage current metal detection circuit device in accordance with the present invention incorporates the use of the metal detection wire and the additional signal wire, and the metal detection wire and the additional signal wire are connected to the sensing end S1 and the sensing end S2. When the metal detection wire is broken, the connection between the sensing end S1 and sensing end S2 is interrupted so that the detection device can detect the interruption promptly, enabling timely detection of leakage current risks, allowing maintenance personnel to perform timely repairs, and reducing the occurrence of hazardous accidents.

### BRIEF DESCRIPTION OF THE DRAWINGS

FIG. 1 is an exploded schematic diagram of the present invention;

FIG. 2 is a cross-sectional view of the present invention;

FIG. 3 is a cross-sectional view of the core wire of the present invention;

FIG. 4 is a signal block diagram of the detection device of the present invention; and

FIG. 5 is a circuit diagram of the detection device of the present invention.

### DETAILED DESCRIPTION OF THE PREFERRED EMBODIMENTS

For a better understanding of those skilled in the art, the following detailed description of the present invention is provided in conjunction with the accompanying drawings and embodiments. The embodiments do not limit the present invention. The following is a detailed description of the present invention with reference to the drawings.

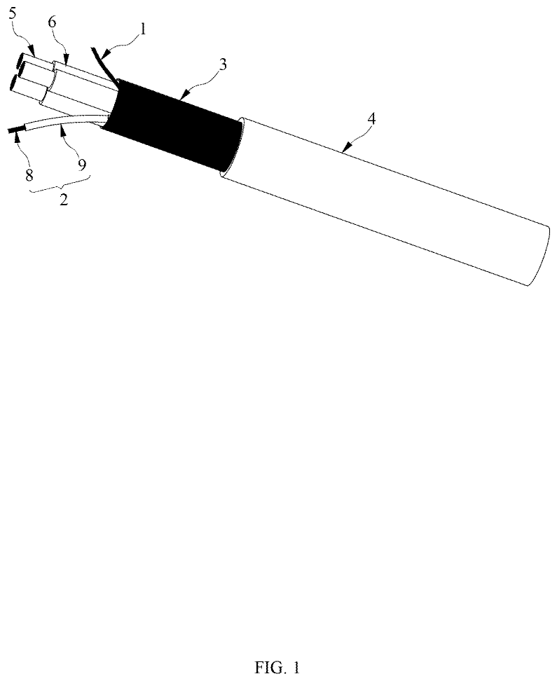

In this embodiment, a leakage current metal detection wire circuit device is provided, as shown in FIGS. 1 to 5, which comprises a detection wire and a detection device. The detection wire comprises a metal detection wire 1, an additional signal wire 2, a metal outer layer 3, a protective insulation layer 4, and multiple core wires. The additional signal wire 2, the metal detection wire 1, and the core wires are all wrapped by the metal outer layer 3, which is then enveloped by the protective insulation layer 4. The detection device is equipped with a sensing end S1 and a sensing end S2. One end of the metal detection wire 1 is connected to one end of the additional signal wire 2 and the other end is connected to the sensing end S1, while the other end of the additional signal wire 2 is connected to the sensing end S2. This arrangement allows the detection device to detect if the electrical connection between sensing end S1 and sensing end S2 is interrupted.

Specifically, in this embodiment, commonly used cables are enhanced by adding the metal detection wire 1 and the additional signal wire 2. The metal detection wire 1 is preferably a bare copper wire, and the additional signal wire 2 preferably comprises a second conductor group 8 and a third insulation layer 9 enveloping the second conductor group 8. Since the metal detection wire 1 and the additional signal wire 2 are not used for transmitting current or voltage signals but for detection purposes, their diameters are preferably smaller than the core wires such as live wires or neutral wires. Therefore, if the metal detection wire 1 is left intact and the additional signal wire 2 is broken due to bending or other causes after a long period of use and interrupts the connection between the metal detection wire 1 and the additional signal wire 2, the electrical connection between the sensing end S1 and sensing end S2 is also disconnected, and a signal is then sent to the detection device, which processes the signal of the interruption and alerts the maintenance personnel for further repairment and inspection to prevent accidents. In this embodiment, the metal detection wire 1 and the additional signal wire 2 serve as a pre-warning signal, with the metal detection wire 1 performing the primary detection function and the additional signal wire 2 transmitting the interruption signal to the sensing end S2. When the metal detection wire 1 is signally interrupted due to breakage or some other problems, indicating that the core wires may have problems, it is necessary to notify the maintenance personnel to perform a repair promptly to prevent the occurrence of a safety incident as early as possible.

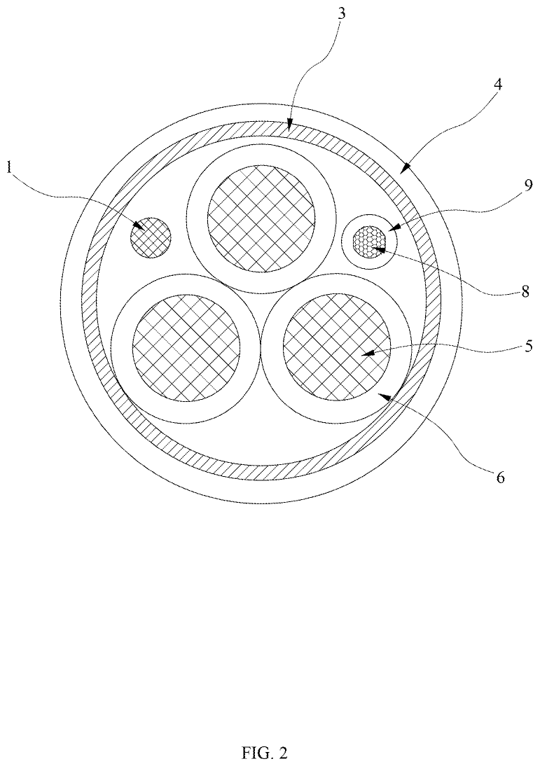

Furthermore, as shown in FIGS. 1 and 2, in this embodiment, the leakage current metal detection wire circuit device also comprises a metal outer layer 3. Preferably, the metal outer layer 3 is made of aluminum foil. The metal outer layer 3 wraps around the metal detection wire 1, the additional signal wire 2, and the multiple core wires, providing a shielding effect against noise and protecting the internal structures in conjunction with the protective insulation layer 4.

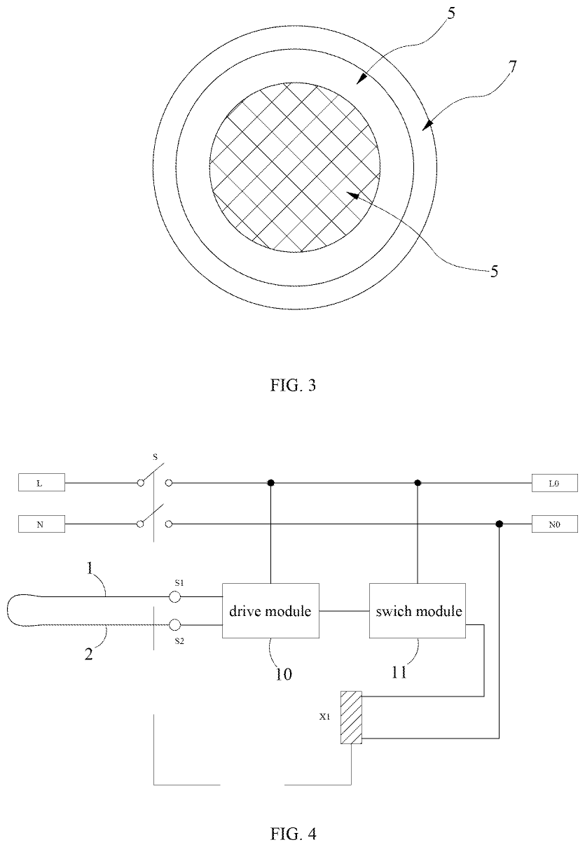

Furthermore, to increase the durability of the core wires, the core wires further comprise a first conductor group 5 and a first insulation layer 6 enveloping the first conductor group 5, with a further second insulation layer 7 as shown in FIG. 3. The first insulation layer 6 and the second insulation layer 7 are used to protect the first conductor group 5 and to reduce the risk of current leakage.

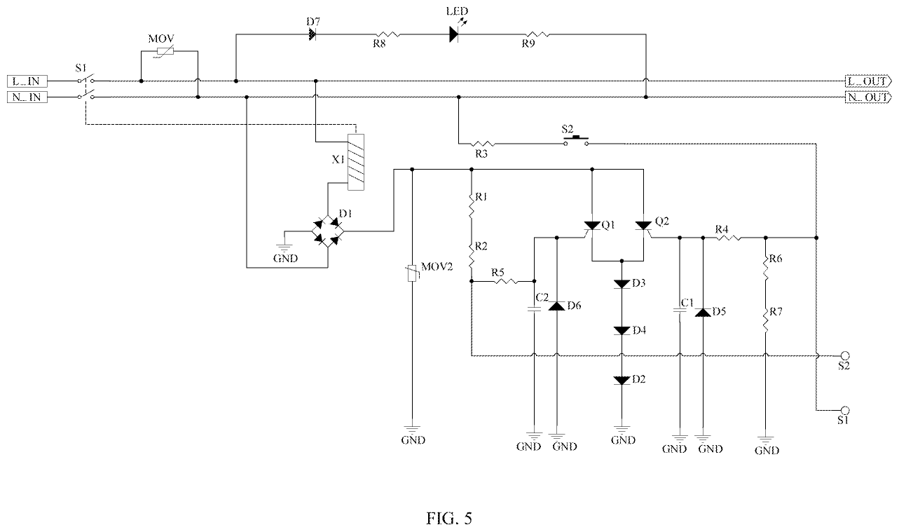

As shown in FIGS. 4 and 5, the specific circuit diagrams of the detection device in this embodiment comprise an input terminal L, an input terminal N, an output terminal LO, and an output terminal NO, further comprising a main switch S1, a drive module 10, a switch module 11, and a circuit breaker X1. The drive module 10 is equipped with the sensing end S1 and the sensing end S2, and the sensing end S1 and the sensing end S2 are connected to the additional signal wire 2 through the metal detection wire 1. The input terminal L is connected to the output terminal LO through the main switch S1, and the input terminal N is also connected to the output terminal NO through the main switch S1. The input of the drive module 10 is connected to the output terminal LO, and the output of the drive module 10 is connected to the control end of the switch module 11. The drive module 10 controls the on/off of the switch module 11 based on the connection signals between the sensing end S1 and sensing end S2. The input of the switch module 11 is connected to the output terminal LO and the output is connected to one voltage end of the circuit breaker X1, while the other voltage end of the circuit breaker X1 is connected to the output terminal NO. The control end of the circuit breaker X1 is connected to the control end of the main switch S1 and is used to control the on/off of the main switch S1.

Specifically, as shown in FIG. 5, in this embodiment, no inductive components such as instrument transformers are required. Instead, with the use of the sensing end S1 and the sensing end S2 are signally connected, for example, using a sensing connection wire to connect the sensing end S1 and sensing end S2. The leakage current detection circuit of this embodiment may optionally be applied to plug sockets whose output is generally a cable. Over time, cables may break and cause current leakage. Thus, by connecting the sensing end S1 and sensing end S2 through the metal detection wire 1 and the additional signal wire 2, respectively, if either the metal detection wire 1 or the additional signal wire 2 is broken, the connection between the sensing end S1 and sensing end S2 will be interrupted, indicating a possible break in the cables used for current and voltage transmission. This condition can be detected by observing the signal connection or disconnection between the sensing end S1 and sensing end S2, and then controlling the on/off of the switch module 11 through the drive module 10, which in turn controls the operation of the circuit breaker X1 to generate a circuit breaker signal, causing the main switch S1 to disconnect and turn off the output voltage to ensure electrical safety.

The input terminal N is connected to a rectifier D1 through the main switch S1. The drive module 10 of this embodiment comprises resistors R5, R18, R4, and R17, and the switch module 11 comprises a diode Q1 and a diode Q2. The resistor R18 is formed by serially connecting the resistor R1 and the resistor R2, while the resistor R17 is formed by serially connecting the resistor R6 and the resistor R7. An anode of the diode Q1 is connected to the output of the rectifier D1, and a cathode of the diode Q1 is grounded. The control end of the diode Q1 is connected to the output of the drive module 10. Similarly, an anode of the diode Q2 is connected to the output of the rectifier D1, and a cathode of the diode Q2 is grounded. The control end of the diode Q2 is connected to the output of the drive module 10. The output of the rectifier D1 is connected sequentially through the resistor R18 and the resistor R5, and then connected to the control end of diode Q1. The connection end between the resistor R18 and the resistor R5 is connected to the sensing end S1. The control end of the diode Q2 is connected sequentially through the resistor R4 and the resistor R17, and then connected to the ground. The connection end between the resistor R4 and the resistor R17 is connected to the sensing end S2. These specific connection relationships are all shown in FIG. 5. The sensing end S1 and sensing end S2 are similarly connected to each other through the sensing connection wire, with the difference from the first embodiment being the circuit connection method of the drive module 10 and the switch module 11.

The specific operating principle of this embodiment is as follows:

When the sensing end S1 and sensing end S2 are normally connected, the voltage is output regularly.

When the connection between the sensing end S1 and sensing end S2 is interrupted, the diode Q1 is conducted through the voltage divided by the resistors R18 and R17, creating a voltage difference at both ends of the circuit breaker X1, thereby controlling the main switch S1 to trip and cut off the voltage output.

When the live or neutral wire shorts with the conductive layer, and the live or neutral wire also shorts with the sensing connection wire, the diode Q2 is conducted through the voltage divided by the resistors R4 and R17, creating a voltage difference at both ends of the circuit breaker X1, thereby controlling the main switch S1 to trip and cut off the voltage output, ensuring the safety of the circuit.

Further, this embodiment comprises a switch S2 for testing whether the leakage current detection functionality of the circuit is operating normally, as shown in FIG. 5. By pressing the switch S2, which can simulate the output control signal of the drive module 10 to control the conduction of the diode Q2, and then testing whether the main switch S1 is tripped, it is possible to test whether the leakage current detection and shutdown functionality of this embodiment is operating normally.

The circuit structure of this embodiment is simple, easy to lay out on a circuit board, and requires fewer components, making the volume of this embodiment smaller.

The above description is only for the preferred embodiments of the present invention and is not intended to limit the present invention. Although the present invention has been disclosed above in its preferred embodiments, it is not intended to limit the present invention. Any person skilled in the art can make some changes or modifications as equivalent embodiments without departing from the scope of the technical solutions of the present invention, and all minor modifications and variations made to the above embodiments based on the technical essence of the present invention fall within the scope of the technical solutions of the present invention.

What is claimed is:

1. A leakage current metal detection circuit device comprising a detection wire and a detection device, the detection wire comprising a metal detection wire, an additional signal wire, a metal outer layer, a protective insulation layer, and multiple core wires, wherein the additional signal wire, the metal detection wire, and the core wires are all wrapped by the metal outer layer, and the metal outer layer is enveloped by the protective insulation layer;
the detection device is equipped with a sensing end S1 and a sensing end S2, wherein one end of the metal detection wire is connected to one end of the additional signal wire and the other end is connected to the sensing end S1, and the other end of the additional signal wire is connected to the sensing end S2, and the detection device detects if the electrical connection between the sensing end S1 and sensing end S2 is interrupted.

2. The leakage current metal detection circuit device according to claim 1, wherein the core wire comprises a first conductor group and a first insulation layer enveloping the first conductor group.

3. The leakage current metal detection circuit device according to claim 1, wherein the metal detection wire is a bare copper wire.

4. The leakage current metal detection circuit device according to claim 1, wherein the additional signal wire comprises a second conductor group and a third insulation layer enveloping the second conductor group.

5. The leakage current metal detection circuit device according to claim 1, wherein the metal outer layer is an aluminum foil layer.

6. The leakage current metal detection circuit device according to claim 1, wherein the core wire further comprises a second insulation layer enveloping the first insulation layer.

7. The leakage current metal detection circuit device according to claim 1, wherein the detection device comprises an input terminal L, an input terminal N, an output terminal LO, an output terminal NO, a main switch S1, a drive module, a switch module, and a circuit breaker X1, and the drive module is equipped with the sensing end S1 and sensing end S2;
the input terminal L is connected to the output terminal LO through the main switch S1, and the input terminal N is also connected to the output terminal NO through the main switch S1; and
the input of the drive module is connected to the output terminal LO and the output is connected to the control end of the switch module; the drive module operates according to the connection signals between the sensing end S1 and sensing end S2 to control the on/off of the switch module; the input of the switch module is connected to the output terminal LO and the output is connected to one voltage end of the circuit breaker X1, while the other voltage end of the circuit breaker X1 is connected to the output terminal NO; the control end of the circuit breaker X1 is connected to the control end of the main switch S1 and is used to control the on/off of the main switch S1.

8. The leakage current metal detection circuit device according to claim 1, wherein the input terminal N is connected to a rectifier D1 through the main switch S1, and the switch module comprises a diode Q1 and a diode Q2, wherein an anode of the diode Q1 is connected to the output of the rectifier D1, and a cathode of the diode Q1 is grounded, the control end of the diode Q1 is connected to the output of the drive module; and wherein an anode of the diode Q2 is connected to the output of the rectifier D1, and a cathode of the diode Q2 is grounded, the control end of the diode Q2 is connected to the output of the drive module.

9. The leakage current metal detection circuit device according to claim 1, wherein the drive module comprises a resistor R5, a resistor R18, a resistor R4, and a resistor R17; the output of the rectifier D1 is connected sequentially through the resistor R18 and the resistor R5 and then connected to the control end of diode Q1, and the connection end between the resistor R18 and the resistor R5 is connected to the sensing end S1; the control end of diode Q2 is connected sequentially through the resistor R4 and the resistor R17 and then connected to the ground, and the connection end between the resistor R4 and the resistor R17 is connected to the sensing end S2.
